(19) United States
(12) Patent Application Publication
(10) Pub. No.: US 2006/0180819 A1
(43) Pub. Date: Aug. 17, 2006

(54) Reflective electrode and compound semiconductor light emitting device including the same

(75) Inventors: Hyun-soo Kim, Yongin-si (KR); Jae-hee Cho, Yongin-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electro-Mechanics Co., Ltd., Suwon-si (KR)

(21) Appl. No.: 11/220,722

(22) Filed: Sep. 8, 2005

(30) Foreign Application Priority Data
Feb. 16, 2005 (KR) 10-2005-0012918

(51) Int. Cl. H01L 33/00

(52) U.S. Cl. 257/94

(57) ABSTRACT

A reflective electrode and a compound semiconductor light emitting device including the same are provided. The reflective electrode formed on a p-type compound semiconductor layer of a compound semiconductor light emitting device including an n-type compound semiconductor layer, an active layer, and the p-type compound semiconductor layer, has an ohmic contact layer formed at a portion of the upper surface of the p-type compound semiconductor layer in a predetermined width, and a reflective electrode layer covering the ohmic contact layer and a portion of the upper surface of the p-type compound semiconductor layer not covered by the ohmic contact layer, wherein contact areas for directly contacting the reflective electrode layer and the p-type compound semiconductor layer are arranged on the upper surface of the p-type compound semiconductor layer.

### CROSS-REFERENCE TO RELATED PATENT APPLICATION

This application claims the benefit of Korean Patent Application No. 10-2005-0012918, filed on Feb. 16, 2005, in the Korean Intellectual Property Office, the disclosure of which is incorporated herein in its entirety by reference.

### BACKGROUND OF THE DISCLOSURE

1. Field of the Disclosure

The present disclosure relates to a reflective electrode and a compound semiconductor light emitting device including the same, and more particularly, to a reflective electrode having an improved light reflective characteristic and current spreading efficiency and a compound semiconductor light emitting device including the same.

2. Description of the Related Art

A laser beam of a semiconductor laser diode, such as a light emitting diode (LED) or a laser diode (LD) that is an example of a compound semiconductor light emitting device converting electric signals into light by using the characteristics of a compound semiconductor, is commercially used and applied in fields such as optical communication, multiple communication, and space communication. The semiconductor laser is widely used as a light source for transferring data and for recording and reading the data in a communication field such as the optical communication or in a device such as a compact disk player (CDP) or a digital versatile disk player (DVDP).

Such a compound semiconductor light emitting device is divided into a top-emitting light emitting diode (TLED) and a flip-chip light emitting diode (FCLED), based on the light emitting direction.

In the TLED, the light is emitted through a p-type electrode, which forms an ohmic contact with a p-type compound semiconductor layer. The p-type electrode is formed by sequentially depositing a nickel layer and a gold layer on the p-type compound semiconductor layer. However, the p-type electrode formed of a nickel layer/gold layer is semi-transparent, and the TLED has the characteristics of low light extraction efficiency and low luminance.

In an FCLED, the light generated from an active layer is reflected from a reflective electrode formed on a p-type compound semiconductor layer, and the reflected light is emitted through a substrate. The reflective electrode is formed of a material having an excellent light reflective characteristic, such as silver, aluminum, or rhodium. The FCLED to which such a reflective electrode is applied has the characteristics of high light extraction efficiency and high luminance. However, since the reflective electrode has a high contact resistance on the p-type compound semiconductor layer, the lifetime of the FCLED is reduced and the character of the FCLED becomes unstable.

In order to address such problems, studies concerning an electrode material and structure having a low contact resistance and a high reflectivity have been performed.

International Patent Publication No. WO 01/47038 A1 discloses a technology involving a semiconductor light emitting device having a reflective electrode. In this case, an ohmic contact layer formed of titanium or nickel/gold is interposed between a reflective electrode and a p-type compound semiconductor layer; however, a light loss occurs because the ohmic contact layer has a high light absorption rate. Accordingly, such a conventional semiconductor light emitting device has the characteristics of low light extraction efficiency and low luminance.

### SUMMARY OF THE DISCLOSURE

The present invention may provide a reflective electrode having the characteristics of improved light reflectivity and current spreading efficiency and a compound semiconductor light emitting device including the same.

According to an aspect of the present invention, there may be provided a reflective electrode formed on a p-type compound semiconductor layer of a compound semiconductor light emitting device including an n-type compound semiconductor layer, an active layer, and the p-type compound semiconductor layer, comprising an ohmic contact layer formed at a portion of the upper surface of the p-type compound semiconductor layer having a predetermined width, and a reflective electrode layer covering the ohmic contact layer and a portion of the upper surface of the p-type compound semiconductor layer not covered by the ohmic contact layer, wherein contact areas for directly contacting the reflective electrode layer and the p-type compound semiconductor layer are arranged on the upper surface of the p-type compound semiconductor layer.

According to another aspect of the present invention, there may be provided a compound semiconductor light emitting device comprising an n-type electrode and a p-type electrode, and an n-type compound semiconductor layer, an active layer, and a p-type compound semiconductor layer therebetween, wherein the p-type electrode includes an ohmic contact layer formed at a portion of the upper surface of the p-type compound semiconductor layer having a predetermined width, and a reflective electrode layer covering the ohmic contact layer and a portion of the upper surface of the p-type compound semiconductor layer not covered by the ohmic contact layer, wherein contact areas for directly contacting the reflective electrode layer and the p-type compound semiconductor layer are arranged on the upper surface of the p-type compound semiconductor layer.

The contact areas may be formed on at least one edge of the upper surface of the p-type compound semiconductor layer corresponding to the n-type electrode, and the contact areas occupy approximately 5 to 60% of the entire area of the upper surface of the p-type compound semiconductor layer. The ohmic contact layer may be formed at the center of the upper surface of the p-type compound semiconductor layer and the contact areas may be formed at the side edges of the upper surface of the p-type compound semiconductor layer.

The ohmic contact layer may be formed of any material selected from Ni, Pt, Pd, Ru, Ir, and Cr, and the ohmic contact layer is formed in a thickness of approximately 10 to 100 Å.

The ohmic contact layer may include sequentially formed first and second metal layers. In this case, the first metal layer is formed of any material selected from the group of Ni, Pt, and Pd, and the second metal layer is of any material selected from the group of Ag, Al, Au, and Rh. The first metal layer may be formed in a thickness of approximately 10 to 100 Å, and the second metal layer may be formed in a thickness of approximately 2,000 to 3,000 Å.

The reflective electrode layer may be formed of any material selected from the group of Ag, Al, Au, and Rh, and the reflective electrode layer may be formed in a thickness of approximately 2,000 to 3,000 Å.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view of a reflective electrode according to a first embodiment of the present invention;

FIG. 2 is a sectional view of a reflective electrode according to a second embodiment of the present invention;

FIG. 3 is a sectional view of a compound semiconductor light emitting device including the reflective electrode of FIG. 1 according to the first embodiment of the present invention;

FIG. 4 is a sectional view of a compound semiconductor light emitting device including the reflective electrode of FIG. 2 according to the second embodiment of the present invention;

FIG. 5 is a graph illustrating changes in the luminance of a light emitting diode (LED) according to the area percentage of an Al-direct contact to the area of the upper surface of a p-type compound semiconductor layer, in other words, a mesa area; and

FIG. 6 is a graph illustrating changes in the operation voltage of an LED according to the area percentage of an Al-direct contact to the area of the upper surface of a p-type compound semiconductor layer, in other words, a mesa area.

### DETAILED DESCRIPTION OF EXEMPLARY EMBODIMENTS

FIG. 1 is a sectional view of a reflective electrode according to a first embodiment of the present invention.

Referring to FIG. 1, a reflective electrode 26 according to the first embodiment of the present invention includes an ohmic contact layer 21 and a reflective electrode layer 25 burying the ohmic contact layer 21.

The ohmic contact layer 21 is interposed between a p-type compound semiconductor layer 10 and the reflective electrode layer 25 in order to reduce the contact resistance of the reflective electrode layer 25. In this case, the ohmic contact layer 21 is formed of any material selected from the group of Ni, Pt, Pd, Ru, Ir, and Cr, and is formed in a thickness of approximately 10 to 100 Å.

The reflective electrode layer 25 is formed of a material having a light reflective characteristic to reflect the light input to the reflective electrode layer 25. The reflective electrode layer 25 is formed of any material selected from the group of Ag, Al, Au, and Ru, and is formed in a thickness of approximately 2,000 to 3,000 Å.

In the reflective electrode 26 according to the first embodiment of the present invention, the ohmic contact layer 21 is formed on a portion of the upper surface of the p-type compound semiconductor layer 10, and the ohmic contact layer 21 and the portion of the upper surface of the p-type compound semiconductor layer 10 not covered by the ohmic contact layer 21 are covered by the reflective electrode layer 25. Accordingly, contact areas 11a and 11b on which the reflective electrode layer 25 and the p-type compound semiconductor layer 10 are directly contacted are arranged on the p-type compound semiconductor layer 10. In the reflective electrode 26 according to the first embodiment of the present invention, the light emitted from the compound semiconductor light emitting device directly reaches the reflective electrode layer 25 at the portions of the contact areas 11a and 11b without passing through the ohmic contact layer 21. Since the ohmic contact layer 21 does not absorb the light at the portions of the contact areas 11a and 11b, the reflective rate of the reflective electrode 26 is improved and the luminance of the compound semiconductor light emitting device is improved. As a result, as the areas of the contact areas 11a and 11b are increased, the light output of the light emitting device is improved. In this case, the contact areas 11a and 11b occupy approximately 5 to 60% of the area of upper surface of the p-type compound semiconductor layer 10.

In a conventional light emitting device, an ohmic contact layer is formed on the entire surface of a p-type compound semiconductor layer that causes a light loss due to the absorption of light by the ohmic contact layer. However, the compound semiconductor light emitting device according to the present invention has contact areas to prevent a light loss due to an ohmic contact layer.

The contact areas 11a and 11b may be formed at least one corner of the upper surface of the p-type compound semiconductor layer 10. The ohmic contact layer 21 may be formed at the center of the upper surface of the p-type compound semiconductor layer 10, and the contact areas 11a and 11b may be formed at both edges of the upper surface of the p-type compound semiconductor layer. In such a reflective electrode 26, the reflective electrode layer 25 and the p-type compound semiconductor layer 10 are directly contacted; thus the contact resistance is partially increased at the contact areas 11a and 11b. However, when the contact areas 11a and 11b are formed at the edges, current crowding can be reduced by the increase in the contact resistance at the edges of the p-type compound semiconductor layer 10. Accordingly, the voltage during operation of the compound semiconductor light emitting device is not increased.

A current crowding effect occurs at the edges of the p-type compound semiconductor layer 10 is disclosed in “Current crowding and optical saturation effects in GaInN/GaN light-emitting diodes grown on insulating substrates”, Applied Physics Letters vol. 78, pp. 3337, 2001. According to the paper, the current crowding effect mainly occurs at a mesa-edge near an n-electrode, in other words, at the edge of the upper surface of the p-type compound semiconductor layer in an FCLED. In addition, the current crowding effect may affect the operation voltage of the LED. In order to reduce the current crowding effect, a current spreading length (Ls) should be increased. In the paper, the Ls is represented by Equation 1.
Lₛ=\sqrt{(ρ_{c+ρ}ₚtₚ)tₙ/ρₙ} [Equation 1]

Here, ρ_{c} denotes the p-contact resistance, ρₚ denotes the p-GaN resistance, tₚ denotes the p-GaN thickness, tₙ denotes the n-GaN thickness, and ρₙ denotes the n-GaN resistance.

In Equation 1, the current crowding effect can be reduced by increasing the p-contact resistance; however, the increase in the p-contact resistance causes the increase in the resistance of the compound semiconductor light emitting device and the operation voltage of the compound semiconductor light emitting device. Accordingly, a method of increasing the p-contact resistance while maintaining the operation voltage of the compound semiconductor light emitting device is required.

In the reflective electrode according to the present invention, the contact areas 11a and 11b having a relatively high p-contact resistance are arranged at the mesa-edges near the n-electrode, in other words, the edges of the upper surface of the p-type compound semiconductor layer where the current crowding primarily occurs. Accordingly, the current crowding effect can be reduced at the edges of the p-type compound semiconductor layer. As a result, the operation voltage of the compound semiconductor light emitting device is not significantly increased regardless of the increase in the contact resistance, due to the release of the current crowding effect at the contact areas 11a and 11b. More specifically, when the contact areas 11a and 11b occupy approximately 5 to 60% of the upper surface of the p-type compound semiconductor layer 10, the operation voltage is not increased regardless of the increase in the contact resistance, because the structure of the reflective electrode according to the first embodiment of the present invention reduces the current crowding effect. In addition, the light output of the LED can be increased by increasing the areas of the contact areas 11a and 11b, in such a reflective electrode 26.

As described above, a reflective electrode having an excellent light reflective characteristic and a current spreading efficiency can be obtained. In addition, such a reflective electrode has an excellent current-voltage characteristic.

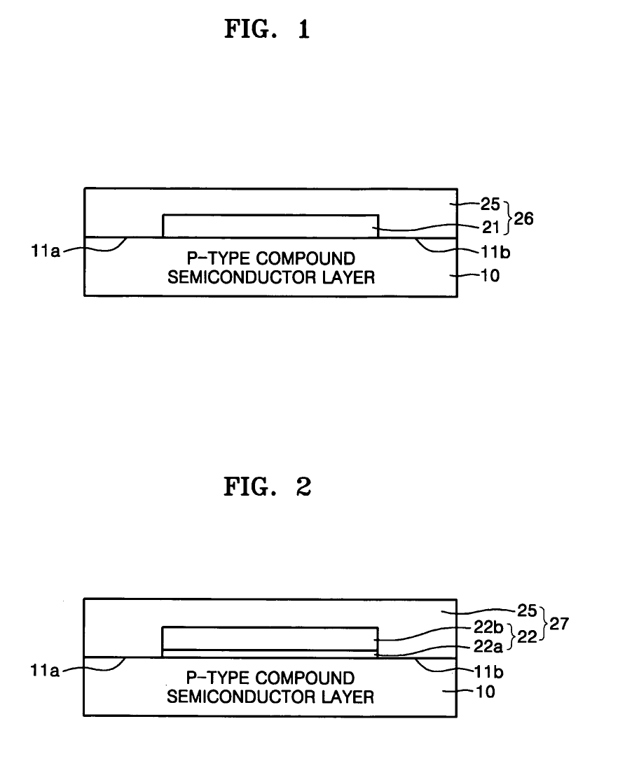

FIG. 2 is a sectional view of a reflective electrode according to a second embodiment of the present invention. In this embodiment, the same elements as those of the reflective electrode according to the first embodiment of the present invention are referred to as same reference numerals, and the descriptions thereof are omitted.

Referring to FIG. 2, a reflective electrode 27 according to the second embodiment of the present invention includes an ohmic contact layer 22 and a reflective electrode layer 25 burying the ohmic contact layer 22. In this case, the ohmic contact layer 22 includes a first metal layer 22a and a second metal layer 22b that are sequentially deposited.

The first metal layer 22a is formed of a material selected from the group of Ni, Pt, and Pd, and is formed in a thickness of approximately 10 to 100 Å. In addition, the second metal layer 22b is formed of a material selected from the group of Ag, Al, Au, and Rh, and formed in a thickness of approximately 2,000 to 3,000 Å.

Contact areas 11a and 11b are arranged in the reflective electrode 27 so that the reflective electrode layer 25 directly contacts a p-type compound semiconductor layer 10. Thus, light emitted from a compound semiconductor light emitting device can directly reach the reflective electrode layer 25 at the contact areas 11a and 11b without passing through the ohmic contact layer 22. Accordingly, the amount of light absorbed by the ohmic contact layer 22 can be reduced, and the reflective rate of the reflective electrode 27 is improved.

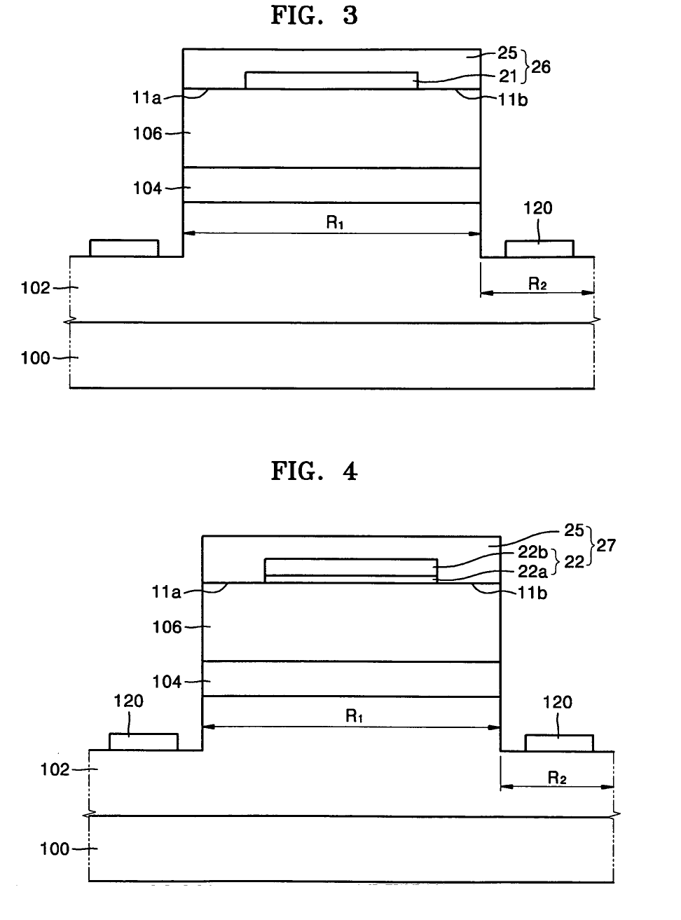

FIG. 3 is a sectional view of a compound semiconductor light emitting device including the reflective electrode of FIG. 1 according to the first embodiment of the present invention.

Referring to FIG. 3, the compound semiconductor light emitting device according to the first embodiment of the present invention includes an n-type electrode 120 and a p-type electrode 26, and an n-type compound semiconductor layer 102, an active layer 104, and a p-type compound semiconductor layer 106 therebetween. In this case, the p-type electrode 26 is the same as the reflective electrode 26 of FIG. 1. In other words, the p-type electrode 26 includes the ohmic contact layer 21 and the reflective electrode layer 25 shown in FIG. 1. The same elements as those shown in FIG. 1 are referred to using the same reference numerals, and the description thereof is omitted.

The n-type compound semiconductor layer 102 includes a first compound semiconductor layer deposited on a substrate 100 and operating as a lower contact layer having a step, and a lower cladding layer deposited on the first compound semiconductor layer. The n-type electrode 120 is located at the step of the first compound semiconductor layer.

The substrate 100 is formed of sapphire or free-standing GaN. The first compound semiconductor layer may be formed of n-GaN based group III-V nitride compound semiconductor or n-GaN. However, the material for the first compound semiconductor layer is not limited, and another group III-V compound semiconductor that possibly oscillates a laser can be used for the first compound semiconductor layer. The lower cladding layer may be formed by an n-GaN/AlGaN layer having a predetermined refractive index; however, the lower cladding layer alternatively may be formed by another compound semiconductor layer that oscillates a laser.

The active layer 104 can be formed of any material that oscillates a laser. The active layer 104 may be formed by a material layer that oscillates a laser having a small critical current value and a stable traverse mode characteristic. The active layer 104 may be formed by a GaN based group III-V nitride compound semiconductor layer including a predetermined amount of aluminum, such as InₓAl_{y}Ga_{1-x-y}N (0≦x≦1, 0≦y≦1, and x+y≦1). In this instance, the active layer 104 may be formed into a multi quantum well structure or a single quantum well structure, and the specific structure of the active layer 104 does not limit the scope of the present invention.

An upper wave guide layer and a lower wave guide layer can be formed on and under the active layer 104, respectively. The upper and lower wave guide layers are formed of a material having a smaller refractive index than the material of the active layer 104. In other words, the upper and lower wave guide layers may be formed by GaN based group III-V compound semiconductor layers. For instance, the lower wave guide layer may be formed by an n-GaN layer and the upper wave guide layer may be formed by a p-GaN layer.

The p-type compound semiconductor layer 106 is deposited on the upper surface of the active layer 104 while including an upper cladding layer having a smaller refractive index than the active layer 104 and a second compound semiconductor layer deposited on the upper cladding layer to operate as an ohmic contact layer. The second compound semiconductor layer may be formed by a p-GaN based group III-V nitride compound semiconductor layer, preferably a p-GaN layer. However, the second compound semiconductor layer alternatively may be formed by any group III-V compound semiconductor layer that oscillates a laser. The upper cladding layer may be formed by a p-GaN/AlGaN layer having a predetermined refractive index or any compound semiconductor layer that oscillates a laser.

The n-type electrode 120 is formed on the step of the first compound semiconductor layer as a lower ohmic contact layer. The n-type electrode 120 may be formed on the lower surface of the substrate 100 in order to face the p-type electrode 26. In this case, the substrate 100 may be formed of silicon carbide (SiC) or gallium nitride (GaN).

Contact areas 11a and 11b are arranged at least one edge on the upper surface of the p-type compound semiconductor layer 106, which corresponds to the n-type electrode 120. The ohmic contact layer 21 may be formed at the center of the upper surface of the p-type compound semiconductor layer 106, and the contact areas 11a and 11b may be formed at the edges of the upper surface of the p-type compound semiconductor layer 106. The reflective electrode layer 25 and the p-type compound semiconductor layer 106 directly contact each other in such a reflective electrode 26; thus the contact resistance is increased at the contact areas 11a and 11b. However, when the contact areas 11a and 11b are formed at mesa-edges near the n-type electrode 120, in other words, at the edges of the p-type compound semiconductor layer 106, the current crowding effect is reduced at the edges of the p-type compound semiconductor layer 106 due to the increase in the contact resistance. Accordingly, the operation voltage of the compound semiconductor light emitting device is not increased.

The compound semiconductor light emitting device including the reflective electrode according to the present invention has characteristics of low operation voltage, an excellent current-voltage characteristic, low power consumption, and high luminance. Accordingly, the compound semiconductor light emitting device with improved light output and light emitting efficiency can be obtained.

FIG. 4 is a sectional view of a compound semiconductor light emitting device including the reflective electrode of FIG. 2 according to the second embodiment of the present invention. In this case, the same elements as those of the compound semiconductor light emitting device of FIG. 3 according to the first embodiment of the present invention are referred to using the same reference numerals, and the descriptions thereof are omitted.

Referring to FIG. 4, the compound semiconductor light emitting device includes an n-type electrode 120 and a p-type electrode 27, and an n-type compound semiconductor layer 102, an active layer 104, and a p-type compound semiconductor layer 106, therebetween. The p-type electrode 27 is the same as the reflective electrode 27 of FIG. 2. In other words, the p-type electrode 27 includes the ohmic contact layer 22 and the reflective electrode layer 25 of FIG. 2. The ohmic contact layer 22 includes a first metal layer 22a and a second metal layer 22b that are sequentially deposited. In addition, the first metal layer 22a is formed of any material selected from the group of Ni, Pt, and Pd, and the second metal layer 22b is formed of any material selected from the group of Ag, Al, Au, and Rh. In this embodiment, the same elements as those shown in FIG. 2 are referred to using the same reference numerals, and the descriptions thereof are omitted.

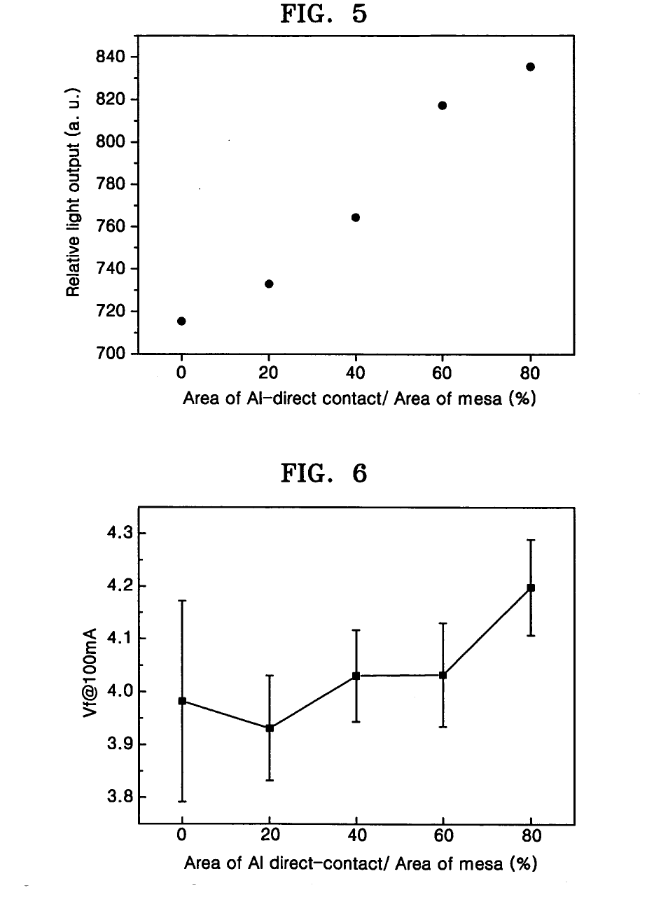

FIG. 5 is a graph illustrating the changes in the luminance of a light emitting diode (LED) according to the area percentage of an Al-direct contact to the area of the upper surface of a p-type compound semiconductor layer, in other words, a mesa area.

FIG. 6 is a graph illustrating the changes in the operation voltage of an LED according to the area percentage of an Al-direct contact to the area of the upper surface of a p-type compound semiconductor layer, in other words, a mesa area.

According to the present invention, a reflective electrode with an improved light reflecting characteristic and current spreading efficiency can be obtained.

The reflective electrode according to the present invention can be applied to a light emitting device, such as an LED or a laser diode (LD), especially, to an FCLED. A compound semiconductor light emitting device including the reflective electrode according to the present invention has a low operation voltage, an excellent current-voltage characteristic, a low power consumption, and high luminance. Accordingly, the compound semiconductor light emitting device has an improved light output and light emitting efficiency.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A reflective electrode formed on a p-type compound semiconductor layer of a compound semiconductor light emitting device including an n-type compound semiconductor layer, an active layer, and the p-type compound semiconductor layer, the reflective electrode comprising:
an ohmic-contact layer formed at a portion of the upper surface of the p-type compound semiconductor layer having a predetermined width; and
a reflective electrode layer covering the ohmic contact layer and a portion of the upper surface of the p-type compound semiconductor layer not covered by the ohmic contact layer, wherein
contact areas for directly contacting the reflective electrode layer and the p-type compound semiconductor layer are arranged on the upper surface of the p-type compound semiconductor layer.

2. The reflective electrode of claim 1, wherein the contact areas are formed on at least one edge of the upper surface of the p-type compound semiconductor layer.

3. The reflective electrode of claim 1, wherein the contact areas occupy approximately 5 to 60% of the entire area of the upper surface of the p-type compound semiconductor layer.

4. The reflective electrode of claim 1, wherein the ohmic contact layer is formed at the center of the upper surface of the p-type compound semiconductor layer and the contact areas are formed at the side edges of the upper surface of the p-type compound semiconductor layer.

5. The reflective electrode of claim 1, wherein the ohmic contact layer is formed of a material selected from the group of Ni, Pt, Pd, Ru, Ir, and Cr.

6. The reflective electrode of claim 5, wherein the ohmic contact layer is formed in a thickness of approximately 10 to 100 Å.

7. The reflective electrode of claim 1, wherein the ohmic contact layer includes sequentially formed first and second metal layers, wherein
the first metal layer is formed of a material selected from the group of Ni, Pt, and Pd, and the second metal layer is formed of a material selected from the group of Ag, Al, Au, and Rh.

8. The reflective electrode of claim 7, wherein the first metal layer is formed in a thickness of approximately 10 to 100 Å, and the second metal layer is formed in a thickness of approximately 2,000 to 3,000 Å.

9. The reflective electrode of claim 1, wherein the reflective electrode layer is formed of a material selected from the group of Ag, Al, Au, and Rh.

10. The reflective electrode of claim 9, wherein the reflective electrode layer is formed in a thickness of approximately 2,000 to 3,000 Å.

11. A compound semiconductor light emitting device comprising: an n-type electrode and a p-type electrode, and an n-type compound semiconductor layer, an active layer, and a p-type compound semiconductor layer, therebetween, wherein
the p-type electrode includes:
an ohmic contact layer formed at a portion of the upper surface of the p-type compound semiconductor layer in a predetermined width; and
a reflective electrode layer covering the ohmic contact layer and a portion of the upper surface of the p-type compound semiconductor layer not covered by the ohmic contact layer, wherein
contact areas for directly contacting the reflective electrode layer and the p-type compound semiconductor layer are arranged on the upper surface of the p-type compound semiconductor layer.

12. The compound semiconductor light emitting device of claim 11, wherein the contact areas are formed on at least one edge of the upper surface of the p-type compound semiconductor layer corresponding to the n-type electrode.

13. The compound semiconductor light emitting device of claim 11, wherein the contact areas occupy approximately 5 to 60% of the entire area of the upper surface of the p-type compound semiconductor layer.

14. The compound semiconductor light emitting device of claim 11, wherein the ohmic contact layer is formed at the center of the upper surface of the p-type compound semiconductor layer and the contact areas are formed at the side edges of the upper surface of the p-type compound semiconductor layer.

15. The compound semiconductor light emitting device of claim 11, wherein the ohmic contact layer is formed of a material selected from the group of Ni, Pt, Pd, Ru, Ir, and Cr.

16. The compound semiconductor light emitting device of claim 15, wherein the ohmic contact layer is formed in a thickness of approximately 10 to 100 Å.

17. The compound semiconductor light emitting device of claim 11, wherein the ohmic contact layer includes sequentially formed first and second metal layers, wherein
the first metal layer is formed of a material selected from the group of Ni, Pt, and Pd, and the second metal layer is formed of a material selected from the group of Ag, Al, Au, and Rh.

18. The compound semiconductor light emitting device of claim 17, wherein the first metal layer is formed in a thickness of approximately 10 to 100 Å, and the second metal layer is formed in a thickness of approximately 2,000 to 3,000 Å.

19. The compound semiconductor light emitting device of claim 11, wherein the reflective electrode layer is formed of a material selected from the group of Ag, Al, Au, and Rh.

20. The compound semiconductor light emitting device of claim 19, wherein the reflective electrode layer is formed in a thickness of approximately 2,000 to 3,000 Å.
